(19) United States
(12) Patent Application Publication
(10) Pub. No.: US 2025/0364286 A1
(43) Pub. Date: Nov. 27, 2025

(54) INFORMATION PROCESSING APPARATUS AND PROCESS CONDITION PREDICTING METHOD

(71) Applicant: Tokyo Electron Limited, Tokyo (JP)

(72) Inventor: Tatsuya YAMAGUCHI, Yamanashi (JP)

(21) Appl. No.: 19/207,721

(22) Filed: May 14, 2025

(30) Foreign Application Priority Data
May 22, 2024 (JP) 2024-083079

(51) Int. Cl. H01L 21/67; C23C 16/52

(52) U.S. Cl. CPC H01L 21/67253; C23C 16/52; H01L 21/67017

(57) ABSTRACT

An information processing apparatus includes: an acquisition unit that acquires a first deposition result obtained by performing deposition on a first wafer with a first layout in a processing container of a substrate processing apparatus having a plurality of regions along a height direction and capable of controlling gas state for each region; a calculation unit that, based on the first deposition result and a second deposition result obtained by performing deposition on a second wafer with the first layout, calculates a change in film thickness between the first and second wafers; and a prediction unit that, based on a third deposition result obtained by performing deposition on a greater number of second wafers with a second layout compared to the first layout and the change in film thickness, predicts the process condition for achieving desired film thickness when performing deposition on the first wafer with the second layout.

### CROSS-REFERENCE TO RELATED APPLICATIONS

This application is based on and claims priority from Japanese Patent Application No. 2024-083079, filed on May 22, 2024, with the Japan Patent Office, the disclosure of which is incorporated herein in its entirety by reference.

### TECHNICAL FIELD

The present disclosure relates to an information processing apparatus and a process condition predicting method.

### BACKGROUND

A batch-type substrate processing apparatus is known, which performs a deposition (e.g., a film forming) on semiconductor wafers (hereinafter, referred to as wafers). While the batch-type substrate processing apparatus may efficiently perform the deposition on the wafers, it is difficult to ensure the uniformity of deposition result. For example, Japanese Patent No. 4464979 discloses a processing system and a processing method, which may adjust the flow rate of a processing gas to achieve the uniformity in thickness of the film deposited on the surface of wafers.

### SUMMARY

According to an aspect of the present disclosure, an information processing apparatus includes: an acquisition unit that acquires a first deposition result obtained by performing a deposition on a first wafer, which is subjected to a process condition prediction, with a first layout in a processing container of a substrate processing apparatus, the substrate processing apparatus having a plurality of regions along a height direction in the processing container and capable of controlling a state of a gas for each region; a calculation unit that, based on the first deposition result and a second deposition result obtained by performing a deposition on a second wafer, which has not been processed, with the first layout in the processing container, calculates a change in film thickness between the first wafer and the second wafer; and a prediction unit that, based on a third deposition result obtained by performing a deposition on a greater number of second wafers with a second layout in the processing container than the first layout and the change in film thickness between the first wafer and the second wafer, predicts the process condition for achieving a desired film thickness when performing a deposition on the first wafer with the second layout.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a configuration of a substrate processing system according to an embodiment of the present disclosure.

FIG. 2 is a view illustrating an example of a hardware configuration of a computer.

FIG. 3 is a view illustrating an example of a hardware configuration of a substrate processing apparatus according to an embodiment of the present disclosure.

FIG. 4 is a view illustrating an example of a hardware configuration of a substrate processing apparatus according to an embodiment of the present disclosure.

FIGS. 5A and 5B are schematic views of an example of a substrate processing apparatus.

FIGS. 6A and 6B are views for describing a problem occurring when predicting a gas flow rate for achieving a desired film thickness of fully-charged device wafers through a deposition, in a substrate processing apparatus in which the state of gas concentration and gas decomposition in a processing container illustrated in FIGS. 5A and 5B is not uniform in the inter-plane direction.

FIGS. 7A and 7B are views for describing a problem occurring when predicting a gas flow rate for achieving a desired film thickness of fully-charged device wafers through a deposition, in the substrate processing apparatus in which the state of gas concentration and gas decomposition in the processing container is not uniform in the inter-plane direction.

FIGS. 8A and 8B are views for describing a case of predicting a gas flow rate for achieving a desired film thickness of fully-charged device wafers through a deposition, in a substrate processing apparatus in which the state of gas concentration and gas decomposition in the processing container is uniform in the inter-plane direction.

FIGS. 9A and 9B are views for describing an example of a resolution of the dependence of a film thickness with respect to a gas flow rate on wafers.

FIGS. 10A and 10B are views for describing an example of a resolution of the dependence of a film thickness with respect to a gas flow rate on the layout of wafers.

FIGS. 11A and 11B are views for describing an example of a resolution of the dependence of a film thickness with respect to a gas flow rate on wafers.

FIG. 12 is a functional block diagram illustrating an example of an apparatus controller according to an embodiment of the present disclosure.

FIGS. 13A and 13B are views illustrating an example of a model in which a gas flow rate corresponds to a film thickness of a deposition result.

FIG. 14 is a flowchart illustrating an example of a process of a substrate processing system according to an embodiment of the present disclosure.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, non-limiting embodiments of the present disclosure will be described with reference to the drawings.

### <System Configuration>

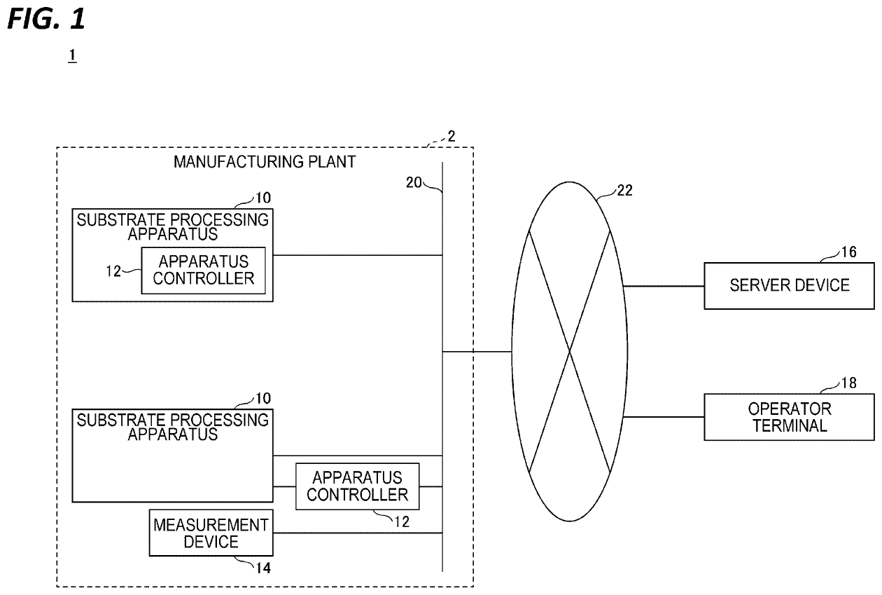

FIG. 1 is a view illustrating an example of the configuration of a substrate processing system 1 according to an embodiment of the present disclosure. The substrate processing system 1 of FIG. 1 includes a substrate processing apparatus 10, an apparatus controller 12, a measurement device 14, a server device 16, and an operator terminal 18. The substrate processing apparatus 10, the apparatus controller 12, and the measurement device 14 are provided in a manufacturing plant 2. The server device 16 and the operator terminal 18 may be provided in the manufacturing plant 2 or at locations other than in the manufacturing plant 2.

The operator terminal 18 is an information processing terminal, such as a personal computer (PC) or a smart phone, which is operated by an operator who is, for example, a person in charge of the substrate processing apparatus 10 provided in the manufacturing plant 2.

The substrate processing apparatus 10, the apparatus controller 12, the measurement device 14, the server device 16, and the operator terminal 18 may be connected to each other for a communication through, for example, the Internet or the local area network (LAN).

The substrate processing apparatus 10 performs a processing of each process (e.g., deposition (film forming), etching, ashing, and cleaning) of a substrate manufacturing process. The substrate processing apparatus 10 may be, for example, a semiconductor manufacturing apparatus, a heat treatment apparatus, or a deposition apparatus. The substrate processing apparatus 10 performs the processing of each process of the substrate manufacturing process, for example, according to the control instructions (process condition) output from the apparatus controller 12.

The process condition refers to a condition for the substrate manufacturing process. The process condition may be a combination of parameters for controlling (adjusting) a control target (control knob) of the substrate processing apparatus 10. The process condition may include a parameter for adjusting the flow rate of a gas.

The apparatus controller 12 may include, for example, a man-machine interface function to receive instructions for the substrate processing apparatus 10 from the operator, and provides the operator with information about the substrate processing apparatus 10. The apparatus controller 12 receives sensor data output from a plurality of sensors provided in the substrate processing apparatus 10. The apparatus controller 12 outputs the process condition to the substrate processing apparatus 10.

While the apparatus controller 12 of FIG. 1 is provided for each substrate processing apparatus 10, the apparatus controller 12 may be provided for multiple substrate processing apparatuses 10. The apparatus controller 12 may be provided inside or outside a case of the substrate processing apparatus 10.

The measurement device 14 is a measuring instrument, such as a film thickness measuring instrument, a sheet resistance measuring instrument, or a particle measuring instrument, which measures a result of a deposition performed by the substrate processing apparatus 10 according to the process condition. For example, the measurement device 14 measures the state of attachment of a film (film thickness) onto a substrate such as a wafer subjected to the deposition by the substrate processing apparatus 10 according to the process condition, as an example of the deposition result. The deposition result may be, for example, a refractive index, an impurity concentration, a roughness, or an electrical characteristic result (specific resistance).

The server device 16 may receive data of the process condition and data of the deposition result of the substrate processing apparatus 10 that has performed the deposition according to the process condition, and store the received data as a process log each time the process is performed (per run), as described herein later. The server device 16 may receive the data of the deposition result from the measurement device 14. Alternatively, the apparatus controller 12 or the operator terminal 18 may receive the data of the process condition and the data of the deposition result of the substrate processing apparatus 10 that has performed the deposition according to the process condition, and store the received data as a process log for each Run. The apparatus controller 12 or the operator terminal 18 may receive the data of the deposition result from the measurement device 14.

By using the stored process log, the apparatus controller 12, the server device 16, or the operator terminal 18 may predict the process condition such as a gas flow rate for achieving a desired film thickness when performing a deposition on wafers with an uncertain gas consumption, and the like, (an example of a first wafer), as described herein later. The wafers with an uncertain gas consumption, and the like, are, for example, device wafers (an example of a product wafer).

The apparatus controller 12 and the server device 16 may display the information about the substrate processing apparatus 10 on the operator terminal 18, or notify the information to the operator of the operator terminal 18 by using, for example, an e-mail. Further, at least one of the apparatus controller 12, the server device 16, and the operator terminal 18 has a function of referring to the layout of device wafers loaded in a wafer boat and predicting the process condition of the substrate processing apparatus 10 for achieving the desired film thickness when performing a deposition with the layout as described herein later. The layout of device wafers loaded in the wafer boat may be, for example, the number of device wafers loaded in the wafer boat or the arrangement of device wafers loaded in the wafer boat. The apparatus controller 12, the server device 16, and the operator terminal 18 of FIG. 1 are an example of an information processing apparatus according to the present embodiment.

The substrate processing system 1 of FIG. 1 is merely an example, and it is obvious that various examples of the configuration of the system exist according to uses or purposes. The division of devices, such as the substrate processing apparatus 10, the apparatus controller 12, the measurement device 14, the server device 16, and the operator terminal 18 in FIG. 1, is an example.

For example, the substrate processing system 1 may be configured in various ways, such as an integrated configuration of two or more of the substrate processing apparatus 10, the apparatus controller 12, the measurement device 14, the server device 16, and the operator terminal 18, or a configuration of further divided devices.

### <Hardware Configuration>

### <<Apparatus Controller, Server Device, and Operator Terminal>>

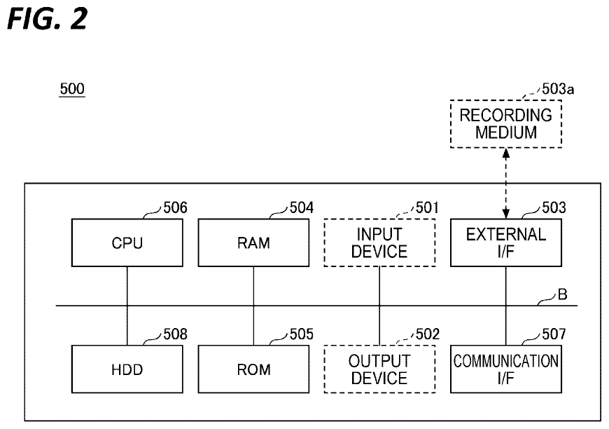

Referring to FIG. 1, the apparatus controller 12, the server device 16, and the operator terminal 18 may be implemented by, for example, a computer having the hardware configuration illustrated in FIG. 2. FIG. 2 is a view illustrating an example of a hardware configuration of a computer 500.

Referring to FIG. 2, the computer 500 includes, for example, an input device 501, an output device 502, an external I/F 503, a random access memory (RAM) 504, a read only memory (ROM) 505, a central processing unit (CPU) 506, a communication I/F 507, and a hard disk drive (HDD) 508, which are connected to each other via a bus B. The input device 501 and the output device 502 may be connected and used when needed.

The input device 501 is, for example, a keyboard, a mouse, or a touch panel, and is used by the operator to input operation signals. The output device 502 is, for example, a display, and displays process results by the computer 500. The communication I/F 507 is an interface that connects the computer 500 to networks 20 and 22 illustrated in FIG. 1. The HDD 508 is an example of a nonvolatile storage device storing programs or data.

The external I/F 503 is an interface with external devices. The computer 500 may perform a read of a recording medium 503a such as a secure digital (SD) memory card through the external I/F 503. The external I/F 503 may perform a write to the recording medium 503a such as an SD memory card through the external I/F 503.

The ROM 505 is an example of a nonvolatile semiconductor memory (storage device) storing programs and data. The RAM 504 is an example of a volatile semiconductor memory (storage device) temporarily storing programs and data. The CPU 506 is a computing device that reads programs and data from the storage device such as the ROM 505 or the HDD 508 into the RAM 504 to execute processes, thereby implementing the overall control and function of the computer 500.

The apparatus controller 12, the server device 16, and the operator terminal 18 of the substrate processing system 1 illustrated in FIG. 1 implement various functions to be described herein later by executing programs on the computer 500 of FIG. 2.

### <<Substrate Processing Apparatus>

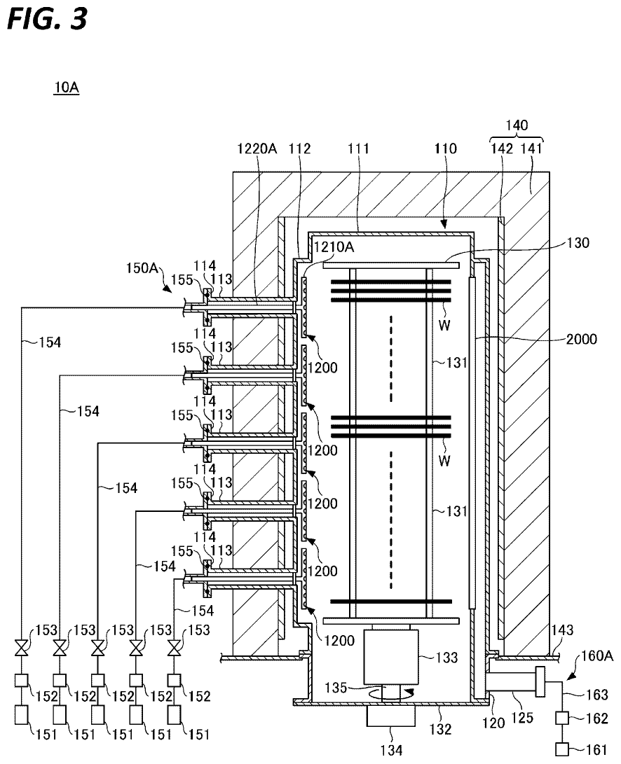

The substrate processing apparatus 10 illustrated in FIG. 1 may be implemented by, for example, a substrate processing apparatus 10A having the hardware configuration illustrated in FIG. 3. FIG. 3 is a view illustrating an example of the hardware configuration of the substrate processing apparatus 10A according to an embodiment of the present disclosure. The substrate processing apparatus 10 is, for example, a deposition apparatus that supplies two or more types of processing gases in an alternate manner to form a film on substrates W such as wafers through an atomic layer deposition (ALD) method.

The substrate processing apparatus 10A includes a processing container 110 such as a cylindrical reaction tube with a ceiling and an opening at the bottom thereof. The entire processing container 110 is formed of, for example, quartz.

At the opening of the bottom of the processing container 110, a metallic flange unit 120 molded in a cylindrical shape is airtightly connected via a seal member such as an O-ring (not illustrated). The flange unit 120 supports the bottom of the processing container 110.

A wafer boat 130 is inserted into the processing container 110 from below the flange unit 120, and in the water boat 130, a plurality of substrates W (e.g., 25 to 150 substrates W) may be arranged in multiple tiers. The wafer boat 130 is an example of a substrate holder. In this way, in the processing container 110, the plurality of substrates W are accommodated substantially horizontally while being spaced apart from each other in the vertical direction. The wafer boat 130 is formed of, for example, quartz. The wafer boat 130 may include, for example, three rods 131 and support the plurality of substrates W by grooves (not illustrated) formed in the rods 131.

A metallic lid 132 is provided below the flange unit 120 to open and close the opening of the bottom of the flange unit 120. The lid 132 is configured to be movable up and down along with the wafer boat 130 by a lift mechanism (not illustrated) such as a boat elevator (not illustrated). A seal member (not illustrated) is provided between the periphery of the lid 132 and the bottom of the flange unit 120 to maintain the airtightness inside the processing container 110.

An insulator 133 formed of quartz is provided between the wafer boat 130 and the lid 132. A rotation mechanism 134 rotates the wafer boat 130 and the insulator 133 around the vertical axis via a rotary shaft 135. The rotary shaft 135 hermetically penetrates the lid 132 to connect the rotation mechanism 134 and the insulator 133 with each other.

In this way, the wafer boat 130 and the lid 132 move up and down in an integrated form by the lift mechanism, thereby being inserted and removed into/from the processing container 110. Further, the wafer boat 130 rotates around the vertical axis by the rotation mechanism 134. The substrate processing apparatus 10A may be configured to perform the processing of the substrates W without rotating the wafer boat 130.

A cylindrical heating mechanism 140 is provided around the processing container 110. The processing container 110, the flange unit 120, and the heating mechanism 140 are supported by a base plate 143 extending in the horizontal direction.

The heating mechanism 140 includes a cylindrical heat insulating member 141 with a ceiling and an opening at the bottom thereof, and a heater 142 disposed on the inner surface of the heat insulating member 141. The heating mechanism 140 heats the processing container 110 by radiant heat from the heater 142 and heat convection. The heating mechanism 140 controls the temperature of the processing container 110 to reach a desired temperature. As a result, the substrates W in the processing container 110 are heated by, for example, radiant heat from the wall surface of the processing container 110. The heating mechanism 140 heats the processing container 110 and the substrates W to a desired temperature.

The substrate processing apparatus 10A further includes a gas supply unit 150A that supplies a gas into the processing container 110, and a gas exhaust unit 160A that exhausts a gas from the inside of the processing container 110.

Here, the processing container 110 includes a ceilinged cylindrical processing container body 111, a gas supply chamber 112, a pipe 113 that is a supply-side pipe, and a flange 114. The processing container body 111 has a ceilinged cylindrical shape, and allows the wafer boat 130 to be inserted thereinto.

The gas supply chamber 112 is formed such that one end side of the lateral surface of the processing container body 111 bulges outwardly while extending along the length direction of the processing container body 111. The interior space of the gas supply chamber 112 is formed to communicate with the interior space of the processing container body 111.

The pipe 113 communicates with the gas supply chamber 112 at one end thereof, and extends in the horizontal direction [the radial direction of the processing container body 111] such that the other end thereof extends to the outer peripheral side than the heating mechanism 40. Further, the flange 114 is provided at the other end of the pipe 113.

An injector 1200 is disposed in the gas supply chamber 112 and the pipe 113. The gas supply unit 50A includes the gas supply chamber 112, the pipe 113, the injector 1200, a gas supply source 151, a flow rate adjustment unit 152, an opening/closing valve 153, a supply path 154, and a gas injector heater (not illustrated).

The gas supply source 151 supplies a gas. The flow rate adjustment unit 152 is, for example, an MFC (mass flow controller), and adjusts the flow rate of the gas supplied from the gas supply source 151. The opening/closing valve 153 switches between the supply of the gas from the gas supply source 151 into the processing container 110 and the stop of the supply. The supply path 154 connects the gas supply source 151 and the pipe 113, and the flow rate adjustment unit 152 and the opening/closing valve 153 are disposed in the middle of the supply path 154.

The supply path 154 and the pipe 113 are connected to each other outside the heating mechanism 140. Further, the connection portions of the supply path 154 and the pipe 113 are airtightly connected via a seal member 155 such as an O-ring. The injector 1200 is disposed spanning through the gas supply chamber 112 and the pipe 113. When a gas is supplied through the supply path 154, the injector 1200 injects the supplied gas into the processing container 110. The gas injector heater heats the pipe 113.

The gas exhaust unit 160A includes an exhaust pipe 125 provided in the side wall of the flange unit 120, a vacuum pump 161, a pressure adjustment unit 162, and an exhaust path 163. Accordingly, the gas in the processing container 110 is exhausted to the outside of the processing container 110 by the gas exhaust unit 160A. The pressure adjustment unit 162 adjusts the pressure in the processing container 110 to a desired pressure.

The injector 1200 includes an injection portion 1210A. The injection portion 1210A has a cylindrical shape having an interior space through which a gas may flow and closed at the upper and lower ends. The injection portion 1210A is a pipe disposed inside the gas supply chamber 112 and extending in the height direction of the processing container 110, when the injector 1200 is attached to the substrate processing apparatus 10A.

In the injection portion 1210A, a gas injection hole is formed to communicate with the interior space of the processing container body 111. A plurality of gas injection holes is formed in the injection portion 1210A in the height direction of the processing container 110. While the injection portion 1210A is described as having the cylindrical shape, the shape of the injection portion 1210A may be, for example, a cylindrical shape having the elliptical cross-sectional area or the polygonal cross-sectional area. In this way, the gas supplied from the gas supply source 151 is supplied into the processing container 110 from the gas injection holes of the injection portion 1210A.

The same type of gas is supplied to a plurality of pipes 113 arranged in the height direction of the processing container body 111. Meanwhile, different types of gases may be supplied to the pipes 113 arranged in the circumferential direction of the processing container body 111.

The pipe 113 is provided extending horizontally from the lateral surface of the processing container body 111, so that the gas inside the injector 1200 may be suppressed from being heated by the heat from the processing container body 111. This improves the controllability of the temperature of the gas injected from the gas injection holes.

Further, the same type of gas is supplied from the plurality of pipes 113 into the processing container 110, so that the flow rate and/or the temperature of the gas may be controlled in the height direction. In this way, since the substrate processing apparatus 10A may control the flow rate and/or the temperature of the gas for each region (zone) in the height direction, the state of gas concentration and gas decomposition in the processing container 110 may be made uniform in the inter-plane direction.

According to the substrate processing apparatus 10A, the gas supplied into the processing container 110 may be adjusted. That is, in the substrate processing apparatus 10A, a plurality of regions (zones) is formed in the height direction of the processing container 110. Then, the injector 1200 corresponds to each region. According to the substrate processing apparatus 10A, as illustrated in FIG. 3, the flow rate of the gas supplied to each of the pipes 113 arranged in the height direction may be individually controlled by the flow rate adjustment unit 152. Thus, the substrate processing apparatus 10A may control the flow rate of the gas supplied to each of the plurality of regions.

Further, according to the substrate processing apparatus 10A, the temperature of a gas supplied may be individually controlled, by individually controlling the gas injector heater provided to correspond to each of the pipes 113 arranged in the height direction. As a result, the substrate processing apparatus 10A may control the temperature of the gas supplied to each of the plurality of regions.

An exhaust slit 2000 is disposed in the lateral surface of an inner tube that the injector 1200 faces. Accordingly, the gas supplied into the processing container 110 from the gas injection holes of the injection portion 1210A passes through the spaces among the substrates W supported in the wafer boat 130 toward the exhaust slit 2000, and is exhausted to the outside of the processing container 110 through the exhaust pipe 125. Thus, the substrate processing apparatus 10A may improve the uniformity of the flow rate and the temperature of the gas supplied by the side flow, and therefore, improve the uniformity of the substrate processing.

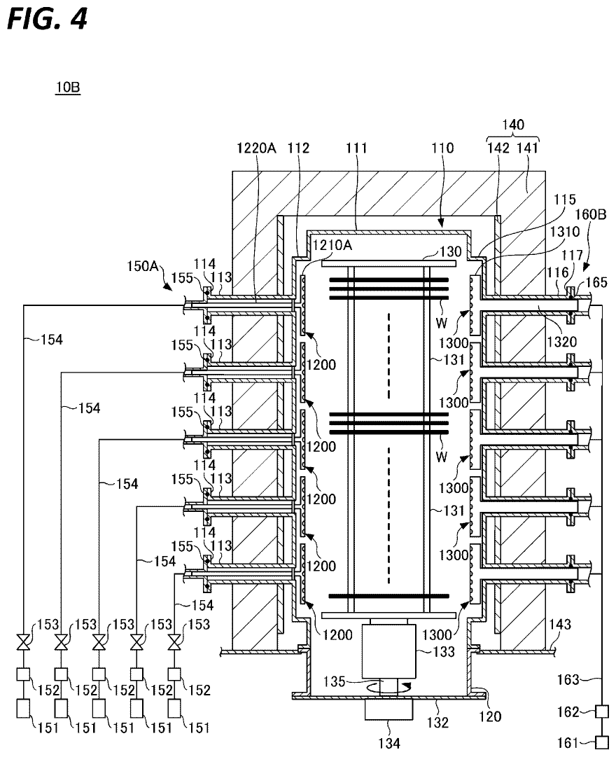

The substrate processing apparatus 10 illustrated in FIG. 1 may be implemented by, for example, a substrate processing apparatus 10B having the hardware configuration illustrated in FIG. 4. FIG. 4 is a view illustrating an example of the hardware configuration of the substrate processing apparatus 10B according to an embodiment of the present disclosure. Since the substrate processing apparatus 10B illustrated in FIG. 4 is the same as the substrate processing apparatus 10A illustrated in FIG. 3, except for some portions thereof, descriptions thereof may be omitted as appropriate.

The substrate processing apparatus 10B includes a gas supply unit 150A that supplies a gas into the processing container 110 and a gas exhaust unit 160B that exhausts a gas from the inside of the processing container 110. The gas supply unit 150A is the same as the gas supply unit 150A of FIG. 3. The processing container 110 includes a processing container body 111 having a cylindrical shape with a ceiling, a gas supply chamber 112, a pipe 113, a flange 114, a gas exhaust chamber 115, a pipe 116 that is an exhaust-side pipe, and a flange 117.

The gas exhaust chamber 115 is formed such that the other end side of the lateral surface of the processing container body 111 bulges outwardly while extending along the length direction of the processing container body 111. The interior space of the gas exhaust chamber 115 communicates with the interior space of the processing container body 111.

The pipe 116 communicates with the gas exhaust chamber 115 at one end thereof, and extends in the horizontal direction [the radial direction of the processing container body 111] while penetrating the side surface of the heating mechanism 140, such that the other end thereof extends to the outer peripheral side than the heating mechanism 140. Further, the flange 117 is provided at the other end of the pipe 116. An ejector 1300 is disposed in the gas exhaust chamber 115 and the pipe 116.

The gas exhaust unit 160B includes the gas exhaust chamber 115, the pipe 116, a vacuum pump 161, a pressure adjustment unit 162, an exhaust path 163, and the ejector 1300. The gas in the processing container 110 is exhausted to the outside of the processing container 110 by the gas exhaust unit 160B. The pressure adjustment unit 162 adjusts the pressure in the processing container 110 to a desired pressure. The pipe 116 and the exhaust path 163 are connected to each other outside the heating mechanism 140. The connection portions of the pipe 116 and the exhaust path 163 are airtightly connected via a seal member 165 such as an O-ring. The ejector 300 is disposed spanning through the gas exhaust chamber 115 and the pipe 116.

The ejector 1300 includes a suction portion 1310. The suction portion 1310 has a cylindrical shape provided with an interior space through which a gas may flow, and closed at the upper and lower ends thereof. The suction portion 1310 is a pipe disposed inside the gas exhaust chamber 115 and extending in the height direction of the processing container 110, when the ejector 1300 is attached to the substrate processing apparatus 10B. In the suction portion 1310, gas suction holes are formed to communicate with the interior space of the processing container body 111. A plurality of gas suction holes is formed in the suction portion 1310 in the height direction of the processing container 110. While the suction portion 1310 is described as having the cylindrical shape, the shape of the suction portion 1310 may be, for example, a cylindrical shape having the elliptical cross-sectional area or the polygonal cross-sectional area.

A transfer portion 1320 is a pipe having the interior space through which a gas may flow, one end thereof is connected to the suction portion 1310 to allow the flow of gas, and the other end thereof is connected to an ejection portion to allow the flow of gas. When the ejector 1300 is attached to the substrate processing apparatus 10B, the transfer portion 1320 is disposed inside the pipe 116. While the transfer portion 1320 is illustrated as having the cylindrical shape, the transfer portion 1320 may be, for example, a pipe having the elliptical cross-sectional area or the polygonal cross-sectional area.

The transfer portion 1320 is formed in a straight-tube shape. As a result, the gas sucked from the gas suction holes of the suction portion 1310 passes through the straight tube-shaped transfer portion 1320, and is exhausted quickly to the ejection portion. The ejection portion is a connection portion connected to the exhaust path 163, and exhausts the gas to the exhaust path 163. In this way, the gas in the processing container 110 flows through the gas suction holes, the suction portion 1310, the transfer portion 1320, and the ejection portion in this order, and is exhausted to the exhaust path 163.

According to the substrate processing apparatus 10B, the flow rate of the gas supplied into the processing container 110 and the gas exhausted from the processing container 110 may be adjusted. That is, in the substrate processing apparatus 10B, a plurality of regions (zone) is formed in the height direction of the processing container 110. The injector 1200 and the ejector 1300 correspond to each region. According to the substrate processing apparatus 10B, as illustrated in FIG. 4, the flow rate of the gas supplied to each of the pipes 113 arranged in the height direction may be individually controlled by the flow rate adjustment unit 152, and the flow rate of the gas discharged from each of the pipes 116 arranged in the height direction may be controlled by the ejector 1300. Further, the ejector 1300 is removable. By replacing the ejector 1300 with an ejector having, for example, a different shape, the substrate processing apparatus 10B may control the flow rate of the gas discharged from each of the plurality of regions.

Accordingly, the gas supplied into the processing container 110 from the gas injection holes of the injection portion 1210A passes through the spaces among the substrates W supported in the wafer boat 130, and is exhausted to the outside of the processing container 110 through the gas suction holes of the suction portion 1310. The substrate processing apparatus 10B may improve the uniformity of the flow rate and the temperature of the gas supplied by the side flow, and therefore, improve the uniformity of the substrate processing.

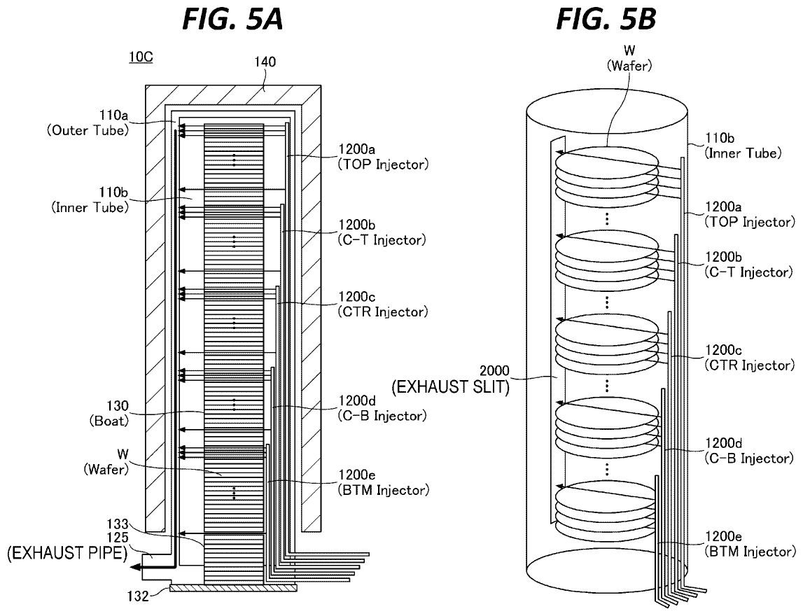

In the related art, the substrate processing apparatus 10 illustrated in FIG. 1 has been implemented by, for example, a substrate processing apparatus 10C having the hardware configuration schematically illustrated in FIGS. 5A and 5B. FIGS. 5A and 5B are views schematically illustrating an example of the substrate processing apparatus 10C. FIGS. 5A and 5B simply illustrate the same portions of the substrate processing apparatus 10C as those of the substrate processing apparatus 10A illustrated in FIG. 3 and the substrate processing apparatus 10B illustrated in FIG. 4.

FIGS. 5A and 5B illustrate the processing container 110 divided into an outer tube 110a and an inner tube 110b. Further, in the substrate processing apparatus 10C illustrated in FIGS. 5A and 5B, the injector 1200 is divided into a top injector 1200a, a center top injector 1200b, a center injector 1200c, a center bottom injector 1200d, and a bottom injector 1200e. Further, in the substrate processing apparatus 10C, the exhaust slit 2000 is disposed in the lateral surface of the inner tube 110b facing the top injector 1200a, the center top injector 1200b, the center injector 1200c, the center bottom injector 1200d, and the bottom injector 1200e inside the inner tube 110b.

According to the substrate processing apparatus 10C, the flow rate of the gas supplied into the processing container 110 and the gas exhausted from the processing container 110 may be adjusted. That is, in the substrate processing apparatus 10C, a plurality of regions (zones) is formed in the height direction of the processing container 110. The top injector 1200a, the center top injector 1200b, the center injector 1200c, the center bottom injector 1200d, and the bottom injector 1200e correspond to the regions, respectively.

As illustrated in FIGS. 5A and 5B, the substrate processing apparatus 10C controls the flow rate of the gas supplied in the height direction of the inner tube 110b, individually by the top injector 1200a, the center top injector 1200b, the center injector 1200c, the center bottom injector 1200d, and the bottom injector 1200e, such that the supplied gas flows on the wafers W toward the exhaust slit 2000.

Accordingly, the gas supplied into the processing container 110 from the top injector 1200a, the center top injector 1200b, the center injector 1200c, the center bottom injector 1200d, and the bottom injector 1200e passes through the spaces among the substrates W supported in the wafer boat 130, and is exhausted to the outside of the processing container 110 through the exhaust slit 2000. However, in the substrate processing apparatus 10C, since the injector 1200 has a different length in each zone, the state of gas may vary in each zone.

### Overview of Present Disclosure

In the present embodiment, descriptions are made on an example where an unprocessed wafer (an example of a second wafer) is a bare wafer, and a wafer with an uncertain gas consumption, and the like, (an example of a first wafer) is a device wafer. The gas consumption of the device wafer varies according to, for example, the surface shape and the type of surface film, which causes different deposition results from those of the bare wafer. The gas consumption of the device wafer also varies according to the layout of device wafers loaded in the wafer boat 130, which causes different deposition results from those of the bare wafer.

For example, in the layout of device wafers when the maximum number of device wafers are loaded in the wafer boat 130 (an example of a second layout), and the layout of device wafers when the smaller number of device wafers than the maximum number of device wafers are loaded in the wafer boat 130 (an example of a first layout), the gas consumption varies, and therefore, different deposition results are obtained. Hereinafter, loading the maximum number of bare wafers or device wafers in the wafer boat 130 will be referred to as a full charge.

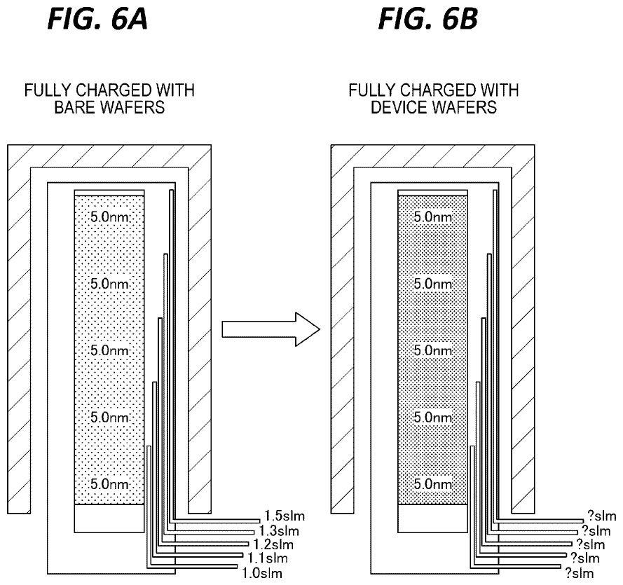

FIGS. 6A and 6B are views for describing a problem occurring when predicting a gas flow rate for achieving a desired film thickness of fully-charged device wafers through a deposition, in a substrate processing apparatus in which the state of gas concentration and gas decomposition in a processing container illustrated in FIGS. 5A and 5B is not uniform in the inter-plane direction.

For example, it is assumed that the operator knows, in advance, the gas flow rate for achieving the target film thickness (e.g., 5 nm) of the bare wafers per region (zone) in the height direction when the bare wafers are fully charged in the wafer boat 130, as illustrated in FIG. 6A.

However, as illustrated in FIG. 6B, it has been difficult to predict the gas flow rate for achieving the target film thickness (5 nm) of the device wafers when the device wafers are fully charged in the wafer boat 130, because the gas consumption differs between the bare wafers and the device wafers according to, for example, the surface shape and the type of surface film.

For example, in the substrate processing apparatus in which the state of gas concentration and gas decomposition in the processing container 110 is not uniform in the inter-plane direction, the first, second, and third factors described below come together, making it difficult to predict the gas flow rate for achieving the target film thickness (5 nm) of the device wafers when the device wafers are fully charged in the wafer boat 130.

The first factor refers to the situation where the distribution of the gas state in the processing container 110 is not uniform due to, for example, different stay times of the gas in the injector 1200 according to the zones. The second factor refers to the situation where the gas consumption differs between the bare wafers and the device wafers. The third factor refers to the situation where the gas consumption varies according to the layout of wafers loaded in the wafer boat 130.

Thus, in order to predict the gas flow rate for achieving the target film thickness (5 nm) of the device wafers when the device wafers are fully charged in the wafer boat 130, it has been necessary to perform a deposition on the device wafers fully charged in the wafer boat 130, and obtain a deposition result.

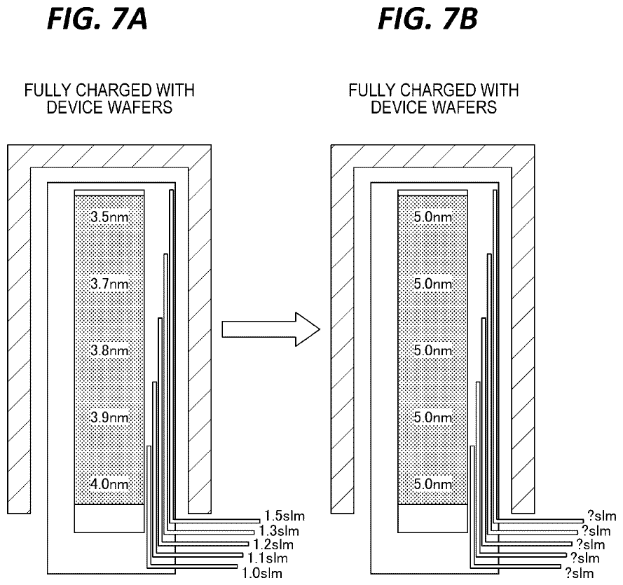

FIGS. 7A and 7B are views for describing a problem occurring when predicting the gas flow rate for achieving the desired film thickness of the fully charged device wafers, in the substrate processing apparatus in which the state of gas concentration and gas decomposition in the processing container 110 is not uniform in the inter-plane direction.

For example, as illustrated in FIG. 7A, the operator performs a deposition in the state where the device wafers are fully charged in the wafer boat 130, and adjusts the gas flow rate for each region (zone) in the height direction such that the deposition result reaches the target film thickness (5 nm). Thus, in order to predict the gas flow rate for achieving the target film thickness (5 nm) of the device wafers fully charged in the wafer boat 130, the operator has needed to repeat the deposition on the device wafers fully charged in the wafer boat 130.

For example, the device wafers are generally expensive, and thus, may not be consumed in bulk to predict the process condition. Further, the device wafers are developed in small quantities at the development stage, and the like, and thus, may not be consumed in bulk to predict the process condition.

Accordingly, when predicting the gas flow rate for achieving the target film thickness (5 nm) of the device wafers fully charged in the wafer boat 130, it is desirable to predict the process condition using as few device wafers as possible.

Therefore, in the present embodiment, it is premised to use the substrate processing apparatuses 10A and 10B in which the state of gas concentration and gas decomposition in the processing container 110 may be made uniform in the inter-plane direction, as illustrated in FIGS. 3 and 4. The first factor described above may be resolved by using the substrate processing apparatuses 10A and 10B in which the state of gas concentration and gas decomposition in the processing container 110 may become uniform in the inter-plane direction.

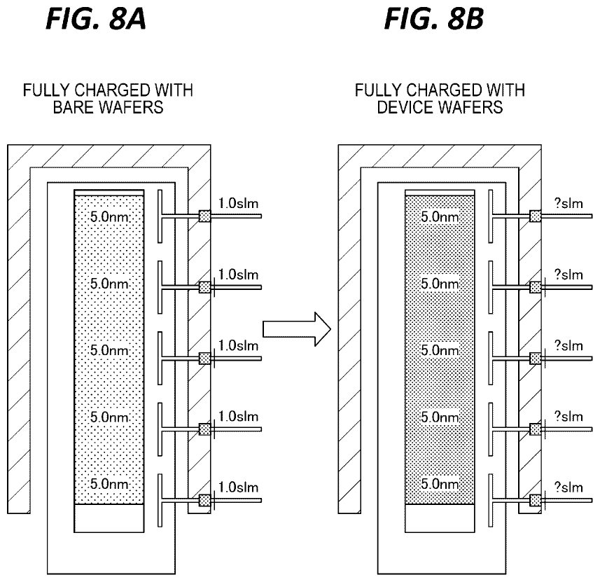

FIGS. 8A and 8B are views for describing an example of predicting the gas flow rate for achieving the desired film thickness of the fully charged device wafers through a deposition, in the substrate processing apparatuses 10A and 10B in which the state of gas concentration and gas decomposition in the processing container 110 is uniform in the inter-plane direction.

For example, it is assumed that the operator knows, in advance, the gas flow rate for achieving the target film thickness (5 nm) of the bare wafers per region (zone) in the height direction, when the bare wafers are fully charged in the wafer boat 130, as illustrated in FIG. 8A. By using the substrate processing apparatuses 10A and 10B in which the state of gas concentration and gas decomposition in the processing container 110 is uniform in the inter-plane direction, the gas flow rate is constant with “1 slm.”

As illustrated in FIG. 8B, the present embodiment predicts the gas flow rate for achieving the target film thickness (5 nm) of the device wafers when the device wafers are fully charged in the wafer boat 130. In the present embodiment, by using the substrate processing apparatuses 10A and 10B in which the state of gas concentration and gas decomposition in the processing container 110 is uniform in the inter-plane direction, the predicted gas flow rate is constant in each region (zone).

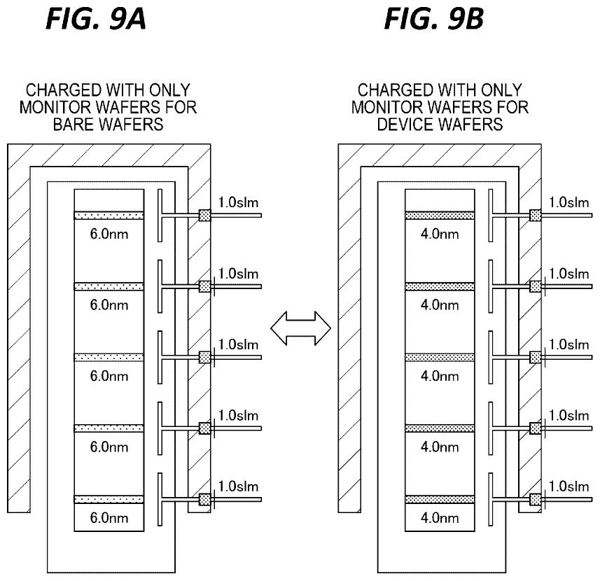

The second factor described above is resolved by calculating a difference in film thickness with respect to the gas flow rate between the bare wafers and the device wafers, as illustrated in, for example, FIGS. 9A and 9B. FIGS. 9A and 9B are views illustrating an example for describing the resolution of the dependence of the film thickness with respect to the gas flow rate on the wafers.

For example, it is assumed that the operator knows in advance that the gas flow rate for achieving the target film thickness (e.g., 6 nm) of the bare wafers is constant with “1 slm” when only monitor wafers for the bare wafers are charged in the wafer boat 130 (a smaller number of bare wafers than that when being fully charged are loaded in the wafer boat 130), as illustrated in FIG. 9A.

Further, as illustrated in FIG. 9B, the operator charges only monitor wafers for the device wafers in the wafer boat 130 (loads a smaller number of device wafers than that when being fully charged in the wafer boat 130), and performs a deposition at the same gas flow rate as that in FIG. 9A to obtain the film thickness “4 nm” as the deposition result.

In the case of FIGS. 9A and 9B, from the film thickness “6 nm” of the bare wafers illustrated in FIG. 9A and the film thickness “4 nm” of the device wafers illustrated in FIG. 9B when the gas flow rate is “1 slm,” the operator may find out that the sensitivity of the film thickness with respect to the gas flow rate for the device wafers is ⅔ times that for the bare wafers. Accordingly, the operator may calculate the dependence of the film thickness with respect to the gas flow rate on the device wafers.

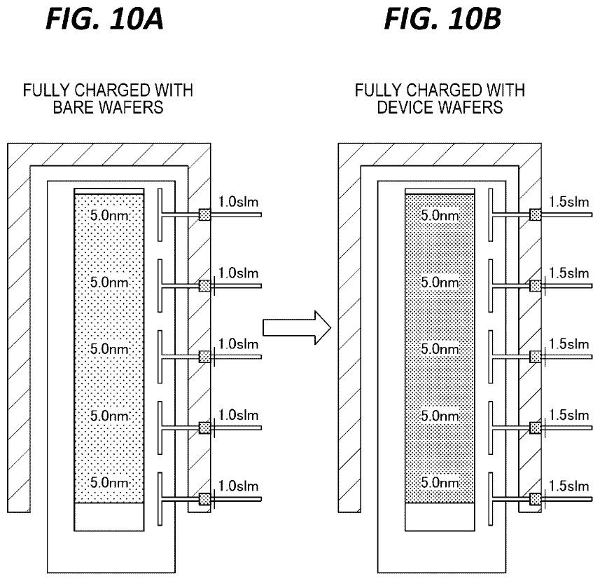

The third factor described above is resolved by predicting the gas flow rate for achieving the target film thickness (5 nm) of the device wafers when the device wafers are fully charged in the wafer boat 130, as illustrated in FIGS. 10A and 10B. FIGS. 10A and 10B are views illustrating an example for describing the resolution of the dependence of the film thickness with respect to the gas flow rate on the layout of wafers.

FIG. 10A illustrates that the gas flow rate for achieving the target film thickness (5 nm) of the bare wafers is constant with “1 slm” per region (zone) in the height direction when the bare wafers are fully charged in the wafer boat 130.

As described using FIGS. 9A and 9B, the sensitivity of the film thickness with respect to the gas flow rate for the device wafers is ⅔ times that for the bare wafers. In the cases of FIGS. 9A, 9B, 10A, and 10B, the operator may calculate “1.5 slm” as the gas flow rate for achieving the target film thickness (5 nm) of the device wafers when the device wafers are fully charged in the wafer boat 130, which is 1.5 times the gas flow rate “1 slm” for achieving the target film thickness (5 nm) of the bare wafers.

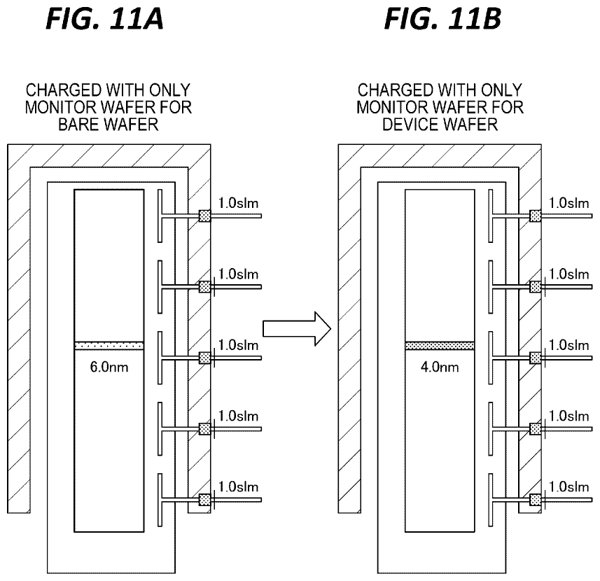

The state where only monitor wafers for the bare wafers or the device wafers are charged in the wafer boat 130 illustrated in FIGS. 9A and 9B is merely an example. The second factor described above may be resolved by calculating a difference in film thickness with respect to the gas flow rate between the bare wafers and the device wafers as illustrated in, for example, in FIGS. 11A and 11B. FIGS. 11A and 11B are views illustrating an example for describing the resolution of the dependence of the film thickness with respect to the gas flow rate on the wafers.

For example, as illustrated in FIG. 11A, it is assumed that the operator knows in advance that the gas flow rate for achieving the target film thickness (6 nm) of the bare wafers is constant with “1 slm” when only one monitor wafer for the bare wafers is charged in the wafer boat 130.

Further, as illustrated in FIG. 11B, the operator charges only one monitor wafer for the device wafers in the wafer boat 130, and performs a deposition at the same gas flow rate as that in FIG. 11A to obtain the film thickness “4 nm” as the deposition result.

In the case of FIGS. 11A and 11B, from the film thickness “6 nm” of the bare wafers illustrated in FIG. 11A and the film thickness “4 nm” of the device wafers illustrated in FIG. 11B when the gas flow rate is “1 slm,” the operator may find out that the sensitivity of the film thickness with respect to the gas flow rate for the device wafers is ⅔ times that for the bare wafers. Thus, the operator may calculate the dependency of the film thickness with respect to the gas flow rate on the device wafers.

### <Functional Configuration>

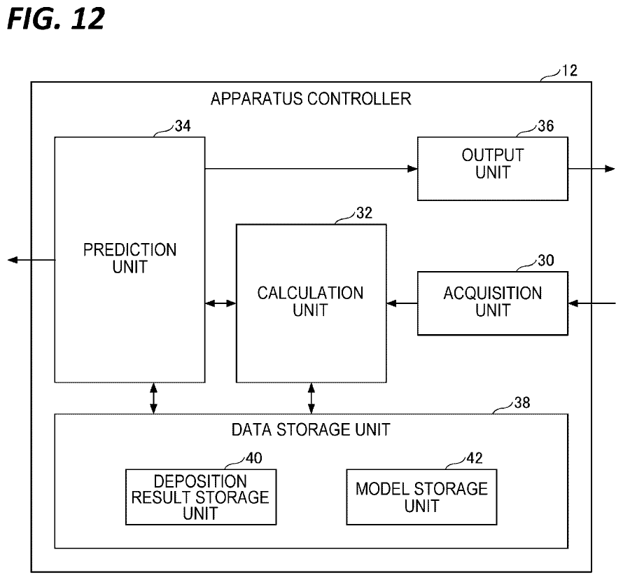

The apparatus controller 12 of the substrate processing system 1 according to the present embodiment is implemented by, for example, the functional blocks illustrated in FIG. 12. FIG. 12 is a functional block diagram illustrating an example of the apparatus controller 12 according the present embodiment. The functional configuration diagram of FIG. 12 omits the illustration of components unnecessary to describe the present embodiment. The functional blocks of FIG. 12 may be implemented in the server device 16 or the operator terminal 18.

The apparatus controller 12 of FIG. 12 executes programs to implement an acquisition unit 30, a calculation unit 32, a prediction unit 34, an output unit 36, and a data storage unit 38. The data storage unit 38 implements a deposition result storage unit 40 and a model storage unit 42.

The acquisition unit 30 acquires a deposition result obtained by performing a deposition on the device wafers subjected to the process condition prediction with, for example, the layout illustrated in FIGS. 9A and 9B or FIGS. 11A and 11B in the processing container 110 (an example of a first deposition result). For example, the acquisition unit 30 may acquire the deposition result of the deposition performed with the layout of FIGS. 9A and 9B or FIGS. 11A and 11B, by receiving an input of the deposition result of the deposition performed with the layout of FIGS. 9A and 9B or FIGS. 11A and 11B from the operator.

Further, the acquisition unit 30 acquires a deposition result obtained by performing a deposition on the bare wafers with, for example, the layout of FIGS. 9A and 9B or FIGS. 11A and 11B in the processing container 110 (an example of a second deposition result). Further, the deposition result obtained by performing a deposition on the bare wafers with the layout of FIGS. 9A and 9B or FIGS. 11A and 11B in the processing container 110 may be stored in advance in the deposition result storage unit 40.

Based on, for example, the deposition result obtained by performing the deposition on the device wafers with the layout of FIGS. 9A and 9B or FIGS. 11A and 11B and the deposition result obtained by performing the deposition on the bare wafers with the layout of FIGS. 9A and 9B or FIG. 11A or 11B, the calculation unit 32 calculates a change in film thickness between the device wafers and the bare wafers (the sensitivity of the film thickness with respect to the gas flow rate for the device wafers based on the bare wafers).

From the difference in film thickness between the device wafers and the bare wafers, the calculation unit 32 calculates the relationship between the gas flow rate when performing the deposition on the device wafers and the gas flow rate when performing the deposition on the bare wafers (the relationship between the change in gas flow rate and the change in film thickness; sensitivity), which is necessary to achieve the same film thickness between the device wafers and the bare wafers.

For example, based on a deposition result obtained by performing a deposition with a specific layout in which a greater number of bare wafers than that in the layout of FIGS. 9A and 9B or FIGS. 11A and 11B are loaded in the wafer boat 130 (an example of a second layout) (an example of a third deposition result), and the change in film thickness between the device wafers and the bare wafers calculated by the calculation unit 32, the prediction unit 34 predicts the process condition such as the gas flow rate for achieving the desired film thickness when performing a deposition on the device wafers with the second layout. The full charge is an example of the second layout.

The prediction unit 34 reflects the relationship calculated by the calculation unit 32 on the third deposition result, to predict the gas flow rate for achieving the desired film thickness when performing a deposition on the device wafers with the second layout.

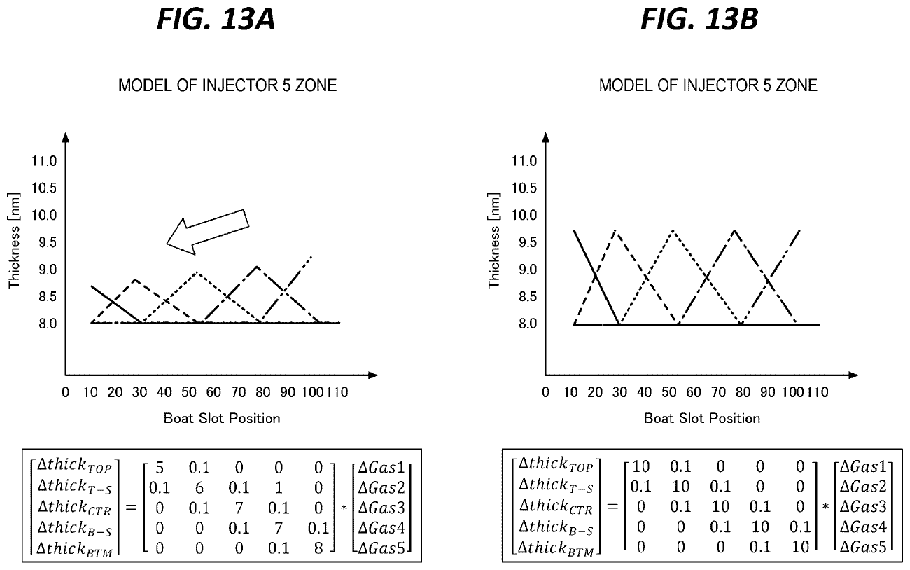

Further, based on the third deposition result obtained by performing the deposition on the bare wafers with the second layout in the processing container 110 and the calculated change in film thickness between the device wafers and the bare wafers, the prediction unit 34 generates the model illustrated in, for example, FIGS. 13A and 13B that represent the correspondence between the gas flow rate and the film thickness when performing the deposition on the device wafers with the second layout, and predicts the gas flow rate for achieving the desired film thickness using the model.

FIGS. 13A and 13B are views illustrating an example of the model representing the correspondence between the gas flow rate and the film thickness that is the deposition result. FIG. 13A is an example of the model for the substrate processing apparatus in which the state of gas concentration and gas decomposition in the processing container 110 is not uniform in the inter-plane direction. FIG. 13A is generated from the amount of change in film thickness when the gas flow rate of the injector in each zone is increased by “0.1 slm” based on a film pressure under a BASE condition. The model of FIG. 13A may not be precise, because the gas state changes between the zones due to the difference in length of the injector 1200, and thus, the amount of deposition is not uniform between the zones.

FIG. 13B is an example of the model for the substrate processing apparatuses 10A and 10B in which the state of gas concentration and gas decomposition in the processing container 110 is uniform in the inter-plane direction. In the model of FIG. 13B, as a result of the side flow, the relationship between the gas flow rate and the film thickness that is the deposition result is diagonalized. The model of FIG. 13B exhibits the high calculation precision, since the gas state does not change between the zones, and the amount of deposition is uniform between the zones. The model of FIG. 13B is stored in, for example, the model storage unit 42.

The output unit 36 outputs the process condition predicted by the prediction unit 34 such as the gas flow rate for achieving the desired film thickness when performing the deposition on the device wafers with the second layout. The output of the process condition is performed by being displayed in, for example, the output device 502.

### Process

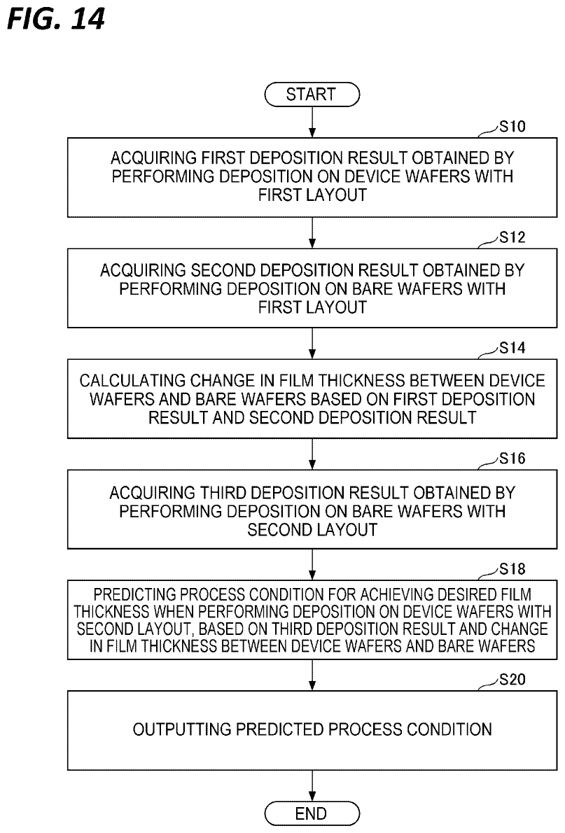

FIG. 14 is a flowchart illustrating an example of the process performed by the substrate processing system 1 according to the present embodiment.

For example, it is assumed that the deposition result storage unit 40 stores deposition results obtained by performing a deposition on the bare wafers with various layouts (including the first layout and the second layout) using the substrate processing apparatuses 10A and 10B in which the state of gas concentration and gas decomposition in the processing container 110 is uniform in the inter-plane direction. Further, it is assumed that the model storage unit 42 stores the model of FIG. 13B for the deposition results stored in the deposition result storage unit 40.

In step S10, the acquisition unit 30 acquires the deposition result obtained by performing the deposition on the device wafers subjected to the process condition prediction with, for example, the layout of FIGS. 9A and 9B or FIGS. 11A and 11B in the processing container 110 (an example of the first deposition result), and transmits the acquired deposition result to the calculation unit 32.

In step S12, the calculation unit 32 acquires the deposition result obtained by performing the deposition on the bare wafers with, for example, the layout of FIGS. 9A and 9B or FIGS. 11A and 11B in the processing container 110 (an example of the second deposition result) from the deposition result storage unit 40.

In step S14, the calculation unit 32 calculates the change in film thickness between the device wafers and the bare wafers, based on the deposition result obtained by performing the deposition on the device wafers with, for example, the layout of FIGS. 9A and 9B or FIGS. 11A and 11B and the deposition result obtained by performing the deposition on the bare wafers with the layout of FIGS. 9A and 9B or FIGS. 11A and 11B.

In step S16, the prediction unit 34 acquires the deposition result obtained by performing the deposition on the bare wafers with, for example, the layout of FIGS. 10A and 10B in the processing container 110 (an example of the third deposition result) from the deposition result storage unit 40.

In step S18, based on the third deposition result and the change in film thickness between the device wafers and the bare wafers that is calculated by the calculation unit 32, the prediction unit 34 predicts the process condition such as the gas flow rate for achieving the desired film thickness when performing a deposition on the device wafers with the second layout.

In step S20, the output unit 36 outputs the process condition predicted by the prediction unit 34 such as the gas flow rate for achieving the desired film thickness when performing a deposition on the device wafers with the second layout.

According to the present embodiment, it is possible to provide the technology, which predicts a process condition for achieving a desired film thickness based on a deposition result obtained from a deposition on a smaller number of device wafers, and therefore, the gas flow rate for achieving a target film thickness of wafers that may not be consumed in large quantities may be predicted precisely.

According to the present disclosure, it is possible to provide a technology, which predicts a process condition for achieving a desired film thickness based on a deposition result obtained from a deposition on a smaller number of wafers.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
acquisition circuitry configured to acquire a first deposition result obtained by performing a deposition on a first wafer, which is subjected to a process condition prediction, with a first layout in a processing container of a substrate processing apparatus, the substrate processing apparatus having a plurality of regions along a height direction in the processing container and capable of controlling a state of a gas for each region;
calculation circuitry configured to, based on the first deposition result and a second deposition result obtained by performing a deposition on a second wafer, which has not been processed, with the first layout in the processing container, calculate a change in film thickness between the first wafer and the second wafer; and
prediction circuitry configured to, based on a third deposition result obtained by performing a deposition on a greater number of second wafers with a second layout in the processing container compared to the first layout and the calculated change in film thickness between the first wafer and the second wafer, predict the process condition for achieving a desired film thickness when performing a deposition on the first wafer with the second layout.

2. The information processing apparatus according to claim 1, wherein from a difference in film thickness between the first wafer and the second wafer, the calculation circuitry calculate a relationship between a flow rate of the gas when performing a deposition on the first wafer and a flow rate of the gas when performing a deposition on the second wafer, the relationship being necessary to achieve same film thickness between the first wafer and the second wafer, and
the prediction circuitry reflect the relationship calculated by the calculation circuitry on the third deposition result, to predict the flow rate of the gas for achieving the desired film thickness when performing the deposition on the first wafer with the second layout.

3. The information processing apparatus according to claim 2, wherein based on the third deposition result obtained by performing the deposition on the greater number of second wafers with the second layout in the processing container compared to the first layout and the calculated change in film thickness between the first wafer and the second wafer, the prediction circuitry generate a model representing a correspondence between the flow rate of the gas when performing the deposition on the first wafer with the second layout and the film thickness of the first wafer, and predict the flow rate of the gas for achieving the desired film thickness using the model.

4. The information processing apparatus according to claim 1, wherein the first layout is a state where only one or more monitor wafers are accommodated in the processing container and held in a substrate holder.

5. The information processing apparatus according to claim 1, wherein the substrate processing apparatus includes a gas supply that supplies a gas from a lateral surface of the processing container along an in-plane direction of the first wafer or the second wafer.

6. The information processing apparatus according to claim 5, wherein the substrate processing apparatus further includes a gas exhaust that exhausts the gas from the lateral surface of the processing container that faces the gas supply.

7. A process condition predicting method comprising:
acquiring a first deposition result obtained by performing a deposition on a first wafer, which is subjected to a process condition prediction, with a first layout in a processing container of a substrate processing apparatus, the substrate processing apparatus having a plurality of regions along a height direction in the processing container and capable of controlling a state of a gas for each region;
based on the first deposition result and a second deposition result obtained by performing a deposition on a second wafer, which has not been processed, with the first layout in the processing container, calculating a change in film thickness between the first wafer and the second wafer; and
based on a third deposition result obtained by performing a deposition on a greater number of second wafers with a second layout in the processing container compared to the first layout and the calculated change in film thickness between the first wafer and the second wafer, predicting the process condition for achieving a desired film thickness when performing a deposition on the first wafer with the second layout.
